(19) United States
(12) Patent Application Publication
(10) Pub. No.: US 2025/0222634 A1
(43) Pub. Date: Jul. 10, 2025

(54) FILM FORMING APPARATUS, FILM FORMING METHOD, AND ARTICLE MANUFACTURING METHOD

(71) Applicant: CANON KABUSHIKI KAISHA, Tokyo (JP)

(72) Inventors: SHUNSUKE OTA, Tochigi (JP); TATSUYA HAYASHI, Tochigi (JP)

(21) Appl. No.: 18/984,201

(22) Filed: Dec. 17, 2024

(30) Foreign Application Priority Data
Jan. 5, 2024 (JP) 2024-000804

(51) Int. Cl. B29C 43/56; B29C 43/02; B29C 43/18

(52) U.S. Cl. CPC B29C 43/56; B29C 43/021; B29C 43/18; B29C 2043/566

(57) ABSTRACT

A film forming apparatus includes a substrate stage including a substrate holder configured to hold a substrate, a mold holder configured to hold a mold, a driving mechanism configured to change an interval between the substrate holder and the mold holder, and a curing device configured to cure a curable composition in a state in which the curable composition arranged on the substrate and the mold contact each other. The substrate stage includes a gas blower configured to supply, to the substrate held by the substrate holder, a gas for inhibiting curing of the curable composition.

### BACKGROUND OF THE INVENTION

### Field of the Invention

The present invention relates to a film forming apparatus, a film forming method, and an article manufacturing method.

### Description of the Related Art

There is known a technique of bringing a curable composition on a substrate and a mold into contact with each other, and curing the curable composition, thereby forming the cured film of the curable composition. A film forming apparatus that uses a mold having a pattern and transfers the pattern to a curable composition can be called an imprint apparatus. A film forming apparatus that uses a mold having a flat surface and forms a cured film having a flat surface can be called a planarization apparatus.

Japanese Patent Laid-Open No. 2022-173919 discloses an imprint apparatus in which while a curable composition in a region of the surface of a substrate where a pattern is formed is irradiated with curing light, a gas (to be referred to as a curing inhibition gas hereinafter) for inhibiting curing of the curable composition is supplied to the periphery of the region. A plurality of gas nozzles for blowing a curing inhibition gas are so arranged as to surround a mold holder that holds a mold, and blow the gas toward a substrate or a substrate holder.

In an arrangement in which gas nozzles for blowing a curing inhibition gas are arranged above a substrate or a substrate holder so as to surround a mold holder, curing inhibition gas supply conditions with respect to the substrate can change every time the position of the substrate changes. It is difficult for this arrangement to process a substrate under fixed conditions.

### SUMMARY OF THE INVENTION

The present invention provides a technique advantageous for processing a substrate under fixed conditions.

A first aspect of the present invention provides a film forming apparatus comprising: a substrate stage including a substrate holder configured to hold a substrate; a mold holder configured to hold a mold; a driving mechanism configured to change an interval between the substrate holder and the mold holder; and a curing device configured to cure a curable composition in a state in which the curable composition arranged on the substrate and the mold contact each other, wherein the substrate stage includes a gas blower configured to supply, to the substrate held by the substrate holder, a gas for inhibiting curing of the curable composition.

A second aspect of the present invention provides a film forming method comprising: bringing a curable composition arranged on a substrate held by a substrate holder and a mold into contact with each other; supplying, from the substrate holder to the substrate held by the substrate holder, a gas for inhibiting curing of the curable composition; curing the curable composition in a state in which the curable composition on the substrate and the mold contact each other, thereby forming a film from a cured product of the curable composition; and separating the film and the mold.

A third aspect of the present invention provides an article manufacturing method comprising: forming a film from a cured product of a curable composition on a substrate by a film forming apparatus defined as the first aspect; and obtaining an article by processing the substrate having undergone the forming.

A fourth aspect of the present invention provides an article manufacturing method comprising: forming a film from a cured product of a curable composition on a substrate by a film forming method defined as the second aspect; and obtaining an article by processing the substrate having undergone the forming.

Further features of the present invention will become apparent from the following description of exemplary embodiments with reference to the attached drawings.

### BRIEF DESCRIPTION OF THE DRAWINGS

FIG. 1 is a view schematically showing the arrangement of a film forming apparatus according to the first embodiment;

FIG. 2 is a flowchart showing a film forming method executed by the film forming apparatus according to the first embodiment;

FIG. 3 is a view schematically showing a state in which the cured film of a curable composition is formed in a partial field;

FIG. 4 is a schematic perspective view showing an example of the structure of a gas blower;

FIG. 5 is a schematic perspective view showing another example of the structure of the gas blower;

FIG. 6 is a view schematically showing the arrangement of a film forming apparatus according to the second embodiment;

FIG. 7 is a flowchart showing a film forming method executed by the film forming apparatus according to the second embodiment;

FIG. 8 is a view schematically showing the arrangement of a film forming apparatus according to the third embodiment;

FIGS. 9A to 9F are views showing an example of an article manufacturing method; and

FIGS. 10A to 10D are views showing another example of the article manufacturing method.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

In the specification and the accompanying drawings, directions will be indicated on an XYZ coordinate system in which directions parallel to the surface of a substrate are defined as the X-Y plane. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are θX, θY, and θZ, respectively. Control or driving concerning the X-axis, the Y-axis, and the Z-axis means control or driving concerning a direction parallel to the X-axis, a direction parallel to the Y-axis, and a direction parallel to the Z-axis, respectively. In addition, control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively. In addition, a position is information that can be specified based on coordinates on the X-, Y-, and Z-axes, and a posture is information that can be specified by values on the θX-, θY-, and θZ-axes. Positioning means controlling the position and/or posture. Alignment can include controlling the position and/or posture of at least one of a substrate and a mold such that the alignment error (overlay error) between the shot region of the substrate and the molding region (region in contact with a curable composition) of the mold decreases. In addition, alignment can include control to correct or change the shape of at least one of the shot region of the substrate and the molding region of the mold.

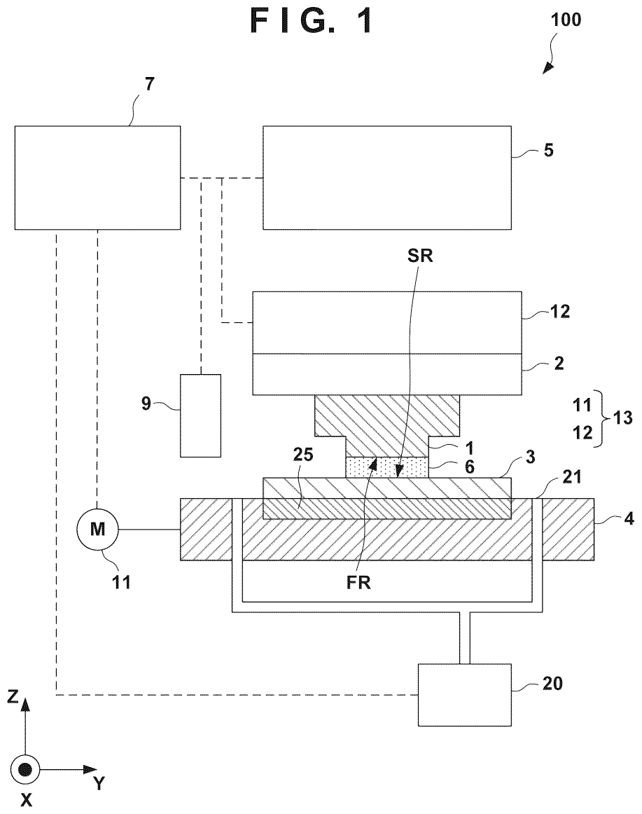

FIG. 1 is a view schematically showing the arrangement of a film forming apparatus 100 according to the first embodiment. The film forming apparatus 100 brings a curable composition 6 on a substrate 3 and a mold 1 into contact with each other, and cures the curable composition 6, thereby forming the cured film of the curable composition 6. The film forming apparatus 100 can be configured as an imprint apparatus that uses the mold 1 having a pattern and transfers the pattern to the curable composition 6. An example in which the film forming apparatus 100 is configured as an imprint apparatus will be explained below. However, the film forming apparatus 100 may be configured as a planarization apparatus that uses the mold 1 having a flat surface and molds the curable composition 6 using the flat surface, thereby forming the cured film having a flat surface.

The curable composition 6 is a composition that is cured by irradiation with light or heating. Among such compositions, a photo-curable composition that is cured by light contains at least a polymerizable compound and a photopolymerization initiator, and if necessary, may contain a nonpolymerizable compound or a solvent. The nonpolymerizable compound is at least one type of material selected from a group consisting of a sensitizer, a hydrogen donor, an internal mold release agent, a surfactant, an antioxidant, a polymer component, and the like. The curable composition 6 can be a monomer such as an acrylate or a methacrylate.

The curable composition 6 is applied like a film onto the substrate 3 by a spin coater or a slit coater. Alternatively, the curable composition 6 may be applied onto the substrate using a liquid injection head, like a droplet or like an island or film formed by connecting a plurality of droplets. The viscosity (viscosity at 25° C.) of an imprint material is, for example, 1 mPa·s (inclusive) to 100 mPa·s (inclusive). The film forming apparatus 100 may include a dispenser 9 that arranges the curable composition 6 on the substrate 3. The dispenser 9 can be configured to discharge the curable composition 6 according to, for example, an inkjet method using a piezoelectric element, or a thermal inkjet method.

A controller 7 controls constituent components of the film forming apparatus 100, for example, a curing device 5, a driving mechanism 13 (a substrate driving mechanism 11 and a mold driving mechanism 12), the dispenser 9, and a gas supplier 20. From another viewpoint, the controller 7 controls the operation of the film forming apparatus 100. The controller 7 can be constituted by, for example, a Programmable Logic Device (PLD) such as a Field Programmable Gate Array (FPGA), an Application Specific Integrated Circuit (ASIC), a general-purpose or dedicated program-installed computer, or all or some of them.

The substrate 3 can be, for example, a silicon wafer, but is not limited to this. The substrate 3 can be a substrate of aluminum, a titanium-tungsten alloy, an aluminum-silicon alloy, an aluminum-copper-silicon alloy, silicon oxide, silicon nitride, or the like. On the substrate 3, a contact layer may be formed by surface processing such as silane coupling processing, silazane processing, or organic thin film formation. The contact layer can improve the adhesion between the curable composition 6 and the substrate 3. Note that the substrate 3 can typically have a circular shape of 300 mm in diameter, but is not limited to this.

The mold 1 can be formed from a material that can transmit curing energy, such as an optically transparent material. The mold 1 can be formed from an optically transparent resin such as glass, quartz, polymethyl methacrylate (PMMA), or a polycarbonate resin. Alternatively, the mold 1 can be formed from a transparent metallized film, a flexible film of polydimethylsiloxane or the like, a photo-cured film, or a metal film. The mold 1 can have a molding region FR that comes into contact with the curable composition 6 in order to mold the curable composition 6. The mold 1 can have, for example, a mesa so that the surface of the mesa forms the molding region FR.

The film forming apparatus 100 can comprise a substrate stage 4 including a substrate holder 25 that holds the substrate 3, and a mold holder 2 that holds the mold 1. The substrate holder 25 and the mold holder 2 can include, for example, a vacuum chuck, an electrostatic chuck, or a mechanical clamp. The film forming apparatus 100 can comprise the driving mechanism 13 that changes the interval between the substrate holder 25 and the mold holder 2. The driving mechanism 13 can be configured to change the interval between the substrate holder 25 and the mold holder 2 so as to bring the mold 1 and the curable composition 6 arranged on the substrate 3 into contact with each other, or separate (the cured product or cured film of) the curable composition 6 and the mold 1 from each other. From another viewpoint, the driving mechanism 13 is configured to, for example, change or adjust the relative position between the substrate holder 25 and the mold holder 2 so as to change or adjust the relative position between the substrate 3 and the mold 1.

The adjustment of the relative position by the driving mechanism 13 can include alignment between (a shot region SR of) the substrate 3 and (the molding region FR of) the mold 1. The driving mechanism 13 can include the substrate driving mechanism 11 that drives the substrate stage 4, and the mold driving mechanism 12 that drives the mold holder 2. The substrate driving mechanism 11 can be configured to drive the substrate 3, the substrate holder 25, or the substrate stage 4 about a plurality of axes (for example, three X-axis, Y-axis, and θZ-axis, and preferably, six X-axis, Y-axis, Z-axis, θX-axis, θY-axis, and θZ-axis). The mold driving mechanism 12 can be configured to drive the mold 1 or the mold holder 2 about a plurality of axes (for example, three Z-axis, θX-axis, and θY-axis, and preferably, six X-axis, Y-axis, Z-axis, θX-axis, θY-axis, and θZ-axis). The mold driving mechanism 12 can include, for example, a deformation mechanism that deforms the mold 1 by applying a force to the side surface of the mold 1.

The film forming apparatus 100 can comprise the curing device 5 that cures the curable composition 6. The curing device 5 can cure the curable composition 6 by applying curing energy to the curable composition 6 in a state in which the curable composition 6 on (the shot region SR of) the substrate 3 and (the molding region FR of) the mold 1 contact each other. The curing energy is, for example, an electromagnetic wave such as ultraviolet light. The curing device 5 can include, as the curing energy source, for example, at least one of a high-pressure mercury lamp, various excimer lamps, an excimer laser, a light emitting diode, and a laser diode.

The substrate stage 4 can include a gas blower 21 that supplies a curing inhibition gas to the substrate 3 held by the substrate holder 25. The curing inhibition gas is a gas that inhibits curing of the curable composition 6 on the substrate 3. The gas blower 21 can be so arranged as to supply the curing inhibition gas to the substrate 3, particularly, the vicinity of the edge of the substrate 3. The film forming apparatus 100 can comprise the gas supplier 20 that supplies the curing inhibition gas to the gas blower 21 so as to supply the curing inhibition gas to the substrate 3. The curing inhibition gas is, for example, an oxygen-containing gas and can be, for example, air. Note that in a state in which a space formed between the shot region (film forming region) SR of the substrate 3 and the molding region FR of the mold 1 is filled with the curable composition 6, the amount of oxygen in the space is ignorable. The gas supplier 20 can include an adjuster that adjusts the gas composition and flow rate of the curing inhibition gas.

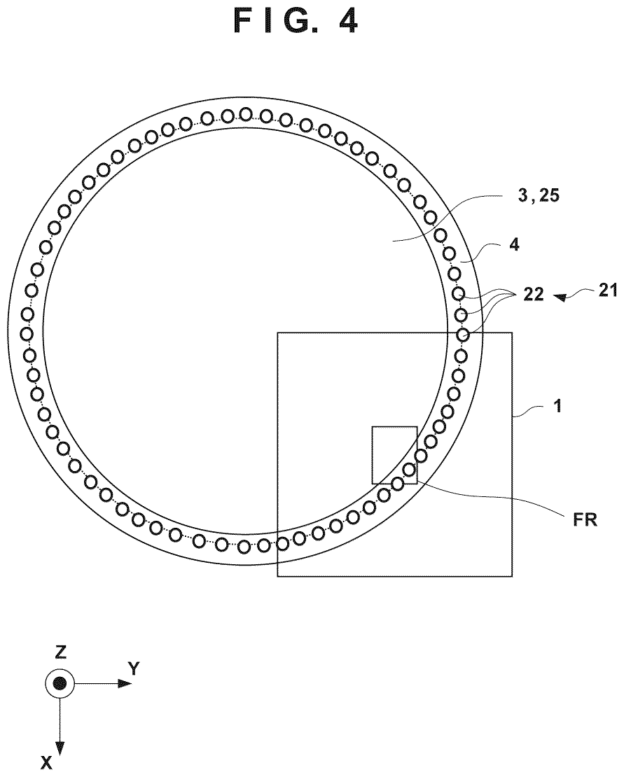

FIG. 4 is a schematic perspective view exemplifying the structure of the gas blower 21. FIG. 4 exemplifies the relative position between the substrate 3 and the mold 1 when forming a cured film in a partial field out of a plurality of shot regions of the substrate 3. The partial field is a shot region defined by the edge of the substrate 3. In other words, the partial field is a shot region whose outer shape is partially defined by an arc along the edge of the substrate 3.

As exemplified in FIG. 4, the gas blower 21 can be so arranged as to surround the substrate 3 held by the substrate holder 25. The gas blower 21 can include a plurality of gas blowholes 22. The plurality of gas blowholes 22 can be arranged at equal intervals on a circle concentric with the center of the substrate 3 held by the substrate holder 25. The gas supplier 20 may supply the curing inhibition gas to at least only one gas blowhole 22 arranged near the shot region SR in accordance with the position of the shot region SR (partial field) where a cured film should be formed.

Alternatively, the plurality of gas blowholes 22 may be divided into a plurality of groups, and the gas supplier 20 may supply the curing inhibition gas to a group corresponding to the position of the shot region SR where a cured film should be formed. Alternatively, a valve may be provided for each group and controlled so that the curing inhibition gas is blown from only a group corresponding to the position of the shot region SR where a cured film should be formed. All or some of the constituent components of the gas supplier 20 may be arranged on the substrate stage 4.

As exemplified in FIG. 5, the gas blower 21 may include a gas blowhole 23 having a ring shape. The center of the ring shape can coincide with that of the substrate 3 held by the substrate holder 25.

The distance between the gas blower 21 and the substrate 3 can fall within the range of 1 mm to 30 mm, and preferably the range of 1 mm to 15 mm.

It is advantageous to provide the gas blower 21 on the substrate stage 4 in order to process a substrate under fixed conditions. By providing the gas blower 21 on the substrate stage 4, the curing inhibition gas can be supplied under fixed conditions to, for example, the substrate 3, particularly, the vicinity of the edge of the substrate 3 regardless of the position of the substrate stage 4. If the gas blower 21 is so arranged as to surround the substrate 3 held by the substrate holder 25, the curing inhibition gas can be supplied under fixed conditions to all the partial field or shot region near the edge of the substrate 3. It is also advantageous to provide the gas blower 21 on the substrate stage 4 in order to reduce the consumption amount of the curing inhibition gas.

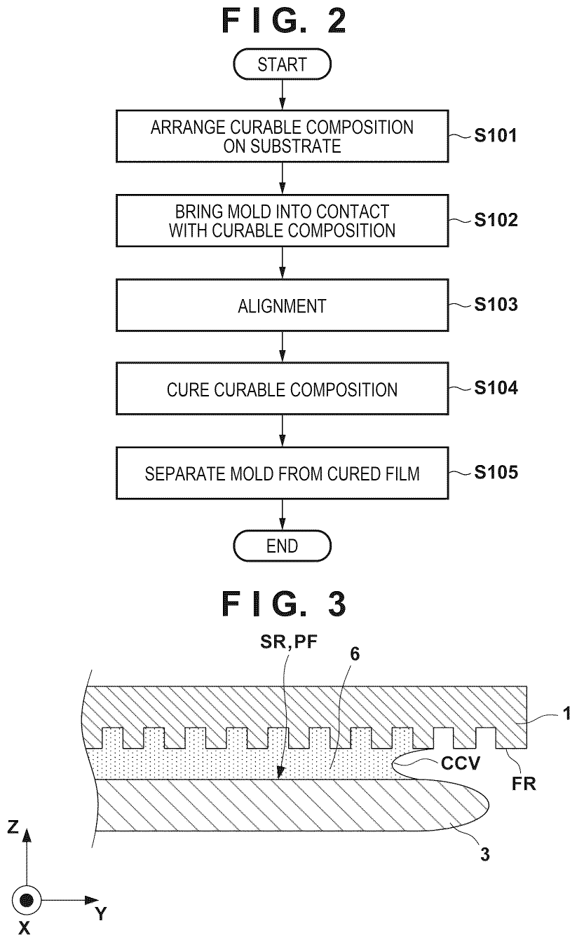

FIG. 2 exemplifies a film forming method executed by the film forming apparatus 100 according to the first embodiment. The controller 7 controls the film forming method. In step S101, the dispenser 9 arranges the uncured curable composition 6 in the shot region SR of the substrate 3. Note that the substrate 3 may be supplied to the film forming apparatus 100 after the curable composition 6 is applied onto the substrate 3. In this case, step S101 can be omitted.

In step S102, the driving mechanism 13 is so controlled as to bring the molding region FR of the mold 1 into contact with the curable composition 6 in the shot region SR of the substrate 3. In step S103, the driving mechanism 13 is so controlled as to align the shot region SR of the substrate 3 and the molding region FR of the mold 1. This alignment can be executed while observing the relative position between the alignment mark of the substrate 3 and that of the mold 1 by using an alignment scope (not shown). Alternatively, this alignment may be executed while observing the outer shape of the substrate 3 and that of the mold 1 by a sensor (not shown).

In step S104, while supplying the curing inhibition gas from the gas blower 21, curing energy is applied from the curing device 5 to the curable composition 6 to cure the curable composition 6 in the shot region SR, thereby forming a cured film from the cured product of the curable composition 6. In step S105, the driving mechanism 13 is so controlled as to separate the mold 1 from the cured film in the shot region SR of the substrate 3.

FIG. 3 schematically shows a state in which the cured film of the curable composition 6 is formed in a partial field PF serving as the shot region SR defined by the edge of the substrate 3. The peripheral portion of the substrate 3 has a beveling portion, so the distance between the substrate 3 and the molding region FR of the mold 1 increases from the center of the substrate 3 toward the edge of the substrate 3. Therefore, when the cured film of the curable composition 6 is formed in the partial field PF, a recess CCV can be formed at the outer portion of the curable composition 6. If the recess CCV at the outer portion of the curable composition 6 is cured, the residue of the cured product of the curable composition 6 can remain in the molding region FR of the mold 1 upon separating the mold 1 from the cured film of the curable composition 6. The residue can remain in a pattern provided in the molding region FR of the mold 1. The residue in the molding region FR of the mold 1 can generate a defect when forming a cured film in the next shot region SR.

To prevent this, when forming the cured film of the curable composition 6 in the partial field PF of the substrate 3, the curing inhibition gas is blown from the gas blower 21 to supply the curing inhibition gas to (the vicinity of the edge of) the substrate 3. This can solve the problem that the residue of the cured product can be formed by curing of the recess CCV. Note that even when forming the cured film of the curable composition 6 in a full field (rectangular shot region SR) of the substrate 3, the curing inhibition gas may be blown from the gas blower 21. Also, even when forming the cured film at once in an entire region of the surface of the substrate 3 where the cured film should be formed, the curing inhibition gas can be blown from the gas blower 21.

The gas blower 21 may be configured to selectively blow the curing inhibition gas or a filling promotion gas. The filling promotion gas is a gas that is superior to air in solubility and diffusion to the curable composition 6, and promotes filling of a space formed between the substrate 3 and the mold 1 with the curable composition 6. As the filling promotion gas, for example, a gas containing at least one of helium gas, nitrogen gas, and a condensable gas (for example, pentafluoropropane (PFP)) is used. The gas supplier 20 can supply the filling promotion gas to the gas blower 21 so as to blow the filling promotion gas from the gas blower 21 before bringing the mold 1 into contact with the curable composition 6 on the substrate 3. The gas supplier 20 can operate so that blowing of the filling promotion gas from the gas blower 21 ends before curing the curable composition 6, and then blowing of the curing inhibition gas from the gas blower 21 starts.

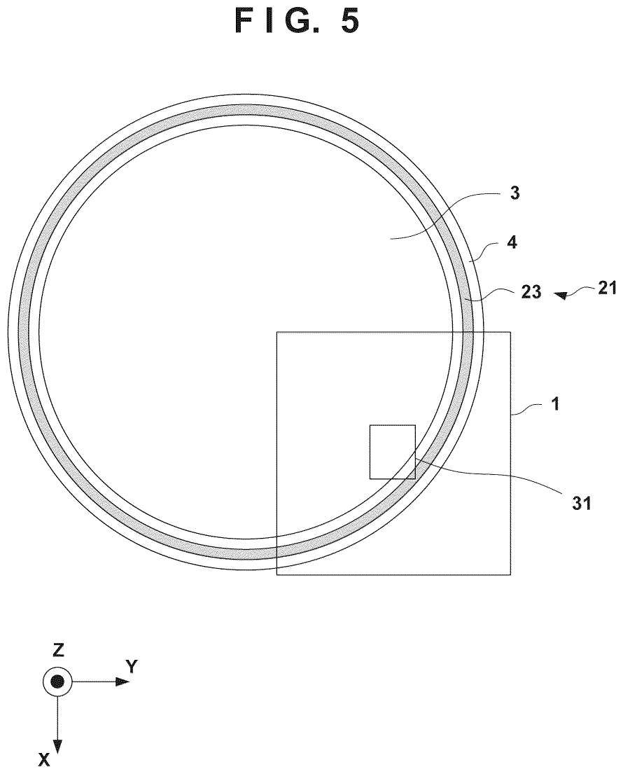

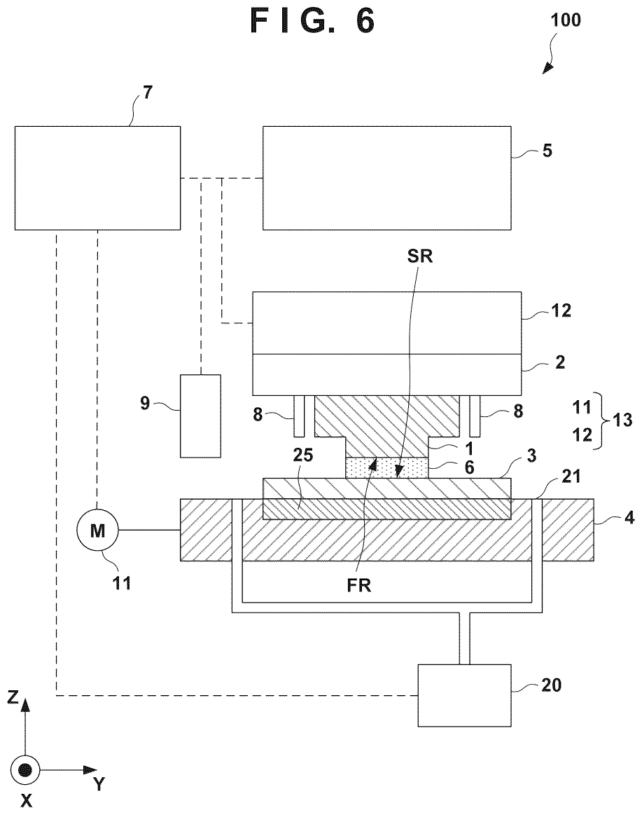

The second embodiment will be described below. Matters which will not be mentioned in the second embodiment can be pursuant to the first embodiment. FIG. 6 is a view schematically showing the arrangement of a film forming apparatus 100 according to the second embodiment. The film forming apparatus 100 according to the second embodiment can comprise an arrangement in which a second gas blower 8 is added to the arrangement of the film forming apparatus 100 according to the first embodiment. The second gas blower 8 can be so arranged as to face a substrate stage 4.

In the first example, the second gas blower 8 is configured to blow a curing inhibition gas for inhibiting curing of a curable composition 6. In the second example, the second gas blower 8 is configured to selectively blow the curing inhibition gas or a filling promotion gas. The second gas blower 8 can be controlled to blow the filling promotion gas before bringing a mold 1 into contact with the curable composition 6 on a substrate 3. The second gas blower 8 can end blowing of the filling promotion gas before curing the curable composition 6, and then start blowing of the curing inhibition gas. A gas blower 21 provided on the substrate stage 4 can start blowing of the curing inhibition gas after the end of blowing of the filling promotion gas by the second gas blower 8 so arranged as to face the substrate stage 4. In the third example, the second gas blower 8 is configured to blow only the filling promotion gas. In this case, the second gas blower 8 can be controlled to start blowing of the filling promotion gas before bringing the mold 1 into contact with the curable composition 6 on the substrate 3, and end the blowing of the filling promotion gas before starting curing of the curable composition 6 by a curing device 5.

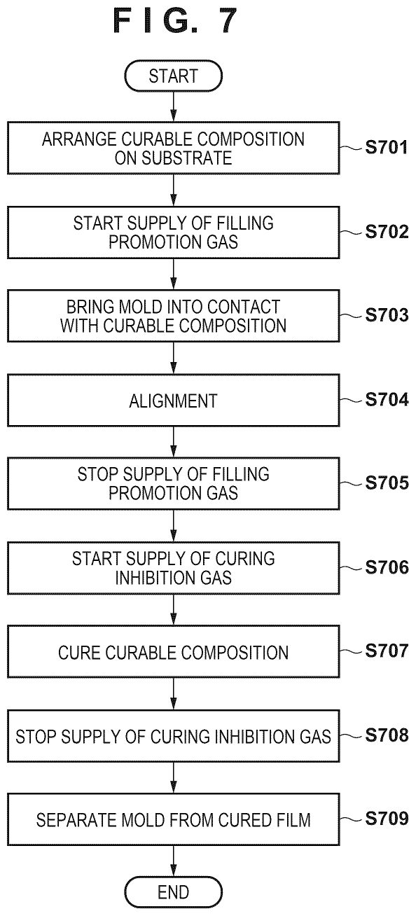

FIG. 7 exemplifies a film forming method executed by the film forming apparatus 100 according to the second embodiment. A controller 7 controls the film forming method. Here, an example in which the second gas blower 8 is configured to blow the filling promotion gas as in the third example will be explained.

In step S701, a dispenser 9 arranges the uncured curable composition 6 in a shot region SR of the substrate 3. Note that the substrate 3 may be supplied to the film forming apparatus 100 after the curable composition 6 is applied onto the substrate 3. In this case, step S701 can be omitted. In step S702, the second gas blower 8 starts blowing of the filling promotion gas. Then, supply of the filling promotion gas to a space between the substrate 3 and the mold 1 starts.

In step S703, a driving mechanism 13 is so controlled as to bring a molding region FR of the mold 1 into contact with the curable composition 6 in the shot region SR of the substrate 3 in a state in which the filling promotion gas exists in the space between the substrate 3 and the mold 1. In step S704, the driving mechanism 13 is so controlled as to align the shot region SR of the substrate 3 and the molding region FR of the mold 1. This alignment can be executed while observing the relative position between the alignment mark of the substrate 3 and that of the mold 1 by using an alignment scope (not shown). Alternatively, this alignment may be executed while observing the outer shape of the substrate 3 and that of the mold 1 by a sensor (not shown).

In step S705, the blowing of the filling promotion gas from the second gas blower 8 stops. The blowing of the filling promotion gas from the second gas blower 8 may stop before the start of alignment in step S704 or during execution of alignment in step S704.

In step S706, blowing of the curing inhibition gas from the gas blower 21 starts. Then, supply of the curing inhibition gas to the vicinity of the edge of the substrate 3 starts. Note that step S706 may be executed only when a shot region where a cured film is formed is a partial field. When step S706 is not executed, step S708 is also not executed.

In step S707, in a state in which the curing inhibition gas is supplied from the gas blower 21, curing energy is applied from the curing device 5 to the curable composition 6 to cure the curable composition 6 in the shot region SR, thereby forming a cured film from the cured product of the curable composition 6. In step S708, the blowing of the curing inhibition gas from the gas blower 21 stops. Note that when the curing inhibition gas is sufficiently supplied to the vicinity of the edge of the substrate 3 before the start of step S707, the blowing of the curing inhibition gas from the gas blower 21 may stop before the start of step S707. In step S709, the driving mechanism 13 is so controlled as to separate the mold 1 from the cured film in the shot region SR of the substrate 3.

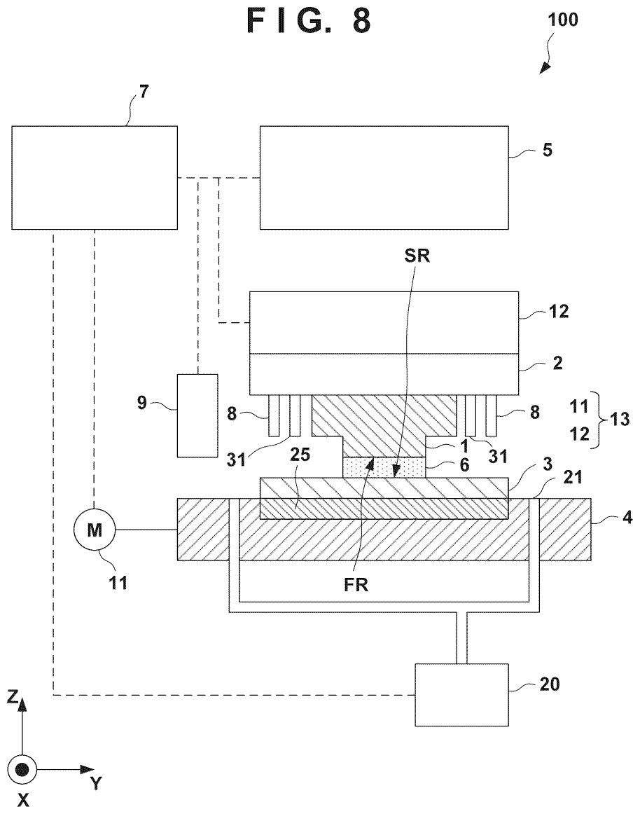

The third embodiment will be described below. Matters which will not be mentioned in the third embodiment can be pursuant to the first and second embodiments. FIG. 8 is a view schematically showing the arrangement of a film forming apparatus 100 according to the third embodiment. The film forming apparatus 100 according to the third embodiment can comprise an arrangement in which a third gas blower 31 is added to the arrangement of the film forming apparatus 100 according to the second embodiment. The third gas blower 31 can be so arranged as to face a substrate stage 4. The third gas blower 31 can be arranged between a second gas blower 8 and a mold 1 held by a mold holder 2. Alternatively, the second gas blower 8 can be arranged between the third gas blower 31 and the mold 1 held by the mold holder 2. In the third embodiment, the second gas blower 8 is configured to blow a filling promotion gas, and the third gas blower 31 is configured to blow a curing inhibition gas.

A film forming method executed by the film forming apparatus 100 according to the third embodiment will be exemplarily explained with reference to FIG. 7. In step S701, a dispenser 9 arranges an uncured curable composition 6 in a shot region SR of a substrate 3. Note that the substrate 3 may be supplied to the film forming apparatus 100 after the curable composition 6 is applied onto the substrate 3. In this case, step S701 can be omitted. In step S702, the second gas blower 8 starts blowing of the filling promotion gas. Then, supply of the filling promotion gas to a space between the substrate 3 and the mold 1 starts.

In step S703, a driving mechanism 13 is so controlled as to bring a molding region FR of the mold 1 into contact with the curable composition 6 in the shot region SR of the substrate 3 in a state in which the filling promotion gas exists in the space between the substrate 3 and the mold 1. In step S704, the driving mechanism 13 is so controlled as to align the shot region SR of the substrate 3 and the molding region FR of the mold 1. This alignment can be executed while observing the relative position between the alignment mark of the substrate 3 and that of the mold 1 by using an alignment scope (not shown). Alternatively, this alignment may be executed while observing the outer shape of the substrate 3 and that of the mold 1 by a sensor (not shown).

In step S705, the blowing of the filling promotion gas from the second gas blower 8 stops. The blowing of the filling promotion gas from the second gas blower 8 may stop before the start of alignment in step S704 or during execution of alignment in step S704.

In step S706, blowing of the curing inhibition gas from a gas blower 21 and the third gas blower 31 starts. Then, supply of the curing inhibition gas to the vicinity of the edge of the substrate 3 starts. Blowing of the curing inhibition gas from the gas blower 21 and that from the third gas blower 31 may start simultaneously or at different timings. Note that step S706 may be executed only when a shot region where a cured film is formed is a partial field. When step S706 is not executed, step S708 is not executed, either.

In step S707, in a state in which the curing inhibition gas is supplied to the edge region of the substrate 3, curing energy is applied from a curing device 5 to the curable composition 6 to cure the curable composition 6 in the shot region SR, thereby forming a cured film from the cured product of the curable composition 6. In step S708, the blowing of the curing inhibition gas from the gas blower 21 stops. Note that when the curing inhibition gas is sufficiently supplied to the vicinity of the edge of the substrate 3 before the start of step S707, the blowing of the curing inhibition gas from at least either of the gas blower 21 and the third gas blower 31 may stop before the start of step S707. In step S709, the driving mechanism 13 is so controlled as to separate the mold 1 from the cured film in the shot region SR of the substrate 3.

An imprint apparatus is an apparatus that brings an imprint material supplied onto a substrate into contact with a mold, and applies curing energy to the imprint material, thereby forming the pattern of a cured product to which the concave-convex pattern of the mold is transferred.

As the imprint material, a curable composition (to be sometimes called a uncured resin) that is cured upon receiving curing energy is used. As the curing energy, electromagnetic waves, radiation, heat, or the like is used. The electromagnetic waves are, for example, light such as infrared light, visible light, or ultraviolet light whose wavelength is selected from the range of 10 nm (inclusive) to 1 mm (inclusive), or may be an electromagnetic radiation such as an X-ray or a gamma ray. The radiation may be a particle radiation such as an electron beam.

The curable composition is a composition cured by irradiation with light or radiation, or heating. Of such curable compositions, a photo-curable composition cured by light contains at least a polymerizable compound and a photopolymerization initiator, and if necessary, may contain a nonpolymerizable compound or a solvent. The nonpolymerizable compound is at least one type of material selected from a group consisting of a sensitizer, a hydrogen donor, an internal mold release agent, a surfactant, an antioxidant, a polymer component, and the like.

The polymerizable compound is a compound that reacts with a polymerizing factor (for example, radical) generated from the photopolymerization initiator, and forms a solid from a polymer compound by a chain reaction (polymerization reaction). An example of the polymerizable compound is a compound having one or more acryloyl groups or methacryloyl groups, that is, a (metha)acrylic compound. The photopolymerization initiator is a compound that generates a polymerizing factor upon receiving light and is, for example, a radical generator such as an acylphosphine oxide compound.

The imprint material may be applied like a film onto the substrate by a spin coater or a slit coater. Alternatively, the imprint material may be applied onto the substrate using a liquid injection head, like a droplet or like an island or film formed by connecting a plurality of droplets. The viscosity (viscosity at 25° C.) of the imprint material is, for example, 1 mPa·s (inclusive) to 100 mPa·s (inclusive).

As the substrate, glass, ceramic, a metal, a semiconductor, a resin, or the like is used, and if necessary, a member made of a material different from that of the substrate may be formed on the surface of the substrate. Examples of the substrate are a silicon wafer, a semiconductor compound wafer, silica glass, and the like. Before applying the imprint material, a contact layer for improving the adhesion between the imprint material and the substrate may be provided, as needed.

The pattern of a cured product formed using the film forming apparatus 100 is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, an SRAM, a flash memory, and an MRAM and semiconductor elements such as an LSI, a CCD, an image sensor, and an FPGA. Examples of the optical element include a microlens, a light guide, a waveguide, an antireflection film, a diffraction grating, a polarizing element, a color filter, a light emitting element, a display, and a solar cell. Examples of the MEMS include a DMD, a microchannel, and an electromechanical conversion element. Examples of the recording element include an optical disk such as a CD or a DVD, a magnetic disk, a magneto-optical disk, and a magnetic head. Examples of the sensor include a magnetic sensor, an optical sensor, and a gyro sensor. The mold includes an imprint mold or the like.

The pattern of the cured product is directly used as at least some of the constituent members of the above-described articles or used temporarily as a resist mask. After etching or ion implantation is performed in the substrate processing step, the resist mask is removed.

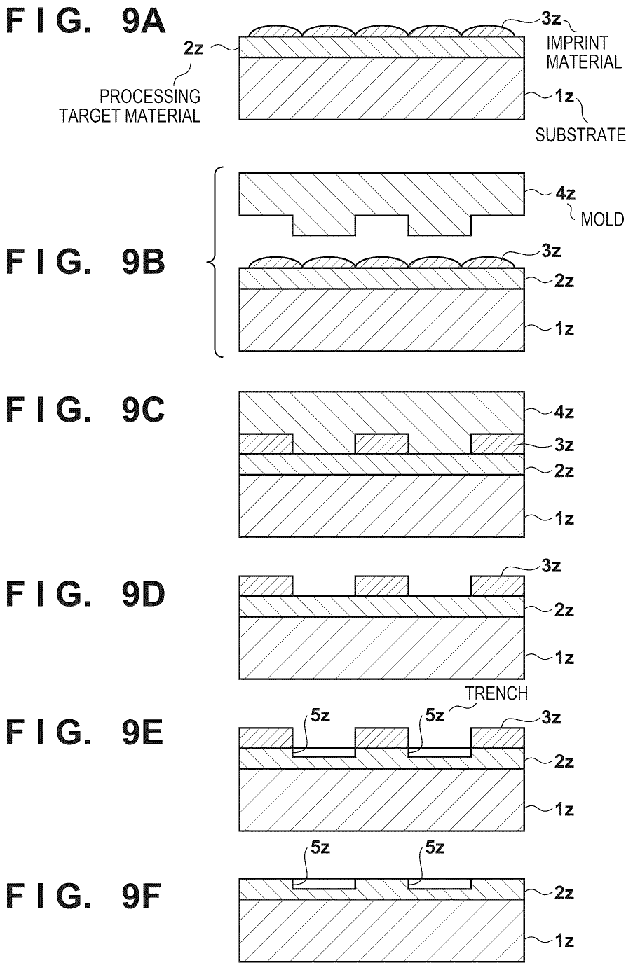

An article manufacturing method in which the film forming apparatus 100 constituted as an imprint apparatus forms a pattern on a substrate, processes the substrate on which the pattern is formed, and manufactures an article from the processed substrate will be described next. As shown in FIG. 9A, a substrate 1z such as a silicon wafer with a processed material 2z such as an insulator formed on the surface is prepared. Next, an imprint material 3z is applied to the surface of the processed material 2z by an inkjet method or the like. A state in which the imprint material 3z is applied as a plurality of droplets onto the substrate is shown here.

As shown in FIG. 9B, a side of a mold 4z for imprint with a concave-convex pattern is directed toward and made to face the imprint material 3z on the substrate. As shown in FIG. 9C, the substrate 1 to which the imprint material 3z is applied is brought into contact with the mold 4z, and a pressure is applied. The gap between the mold 4z and the processed material 2z is filled with the imprint material 3z. In this state, when the imprint material 3z is irradiated with light as energy for curing via the mold 4z, the imprint material 3z is cured.

As shown in FIG. 9D, after the imprint material 3z is cured, the mold 4z is separated from the substrate 1z, and the pattern of the cured product of the imprint material 3z is formed on the substrate 1z. In the pattern of the cured product, the concave portion of the mold corresponds to the convex portion of the cured product, and the convex portion of the mold corresponds to the concave portion of the cured product. That is, the concave-convex pattern of the mold 4z is transferred to the imprint material 3z.

As shown in FIG. 9E, when etching is performed using the pattern of the cured product as an etching resistant mask, a portion of the surface of the processed material 2z where the cured product does not exist or remains thin is removed to form a groove 5z. As shown in FIG. 9F, when the pattern of the cured product is removed, an article with the grooves 5z formed in the surface of the processed material 2z can be obtained. Here, the pattern of the cured product is removed. However, instead of removing the pattern of the cured product after the process, it may be used as, for example, an interlayer dielectric film included in a semiconductor element or the like, that is, a constituent member of an article.

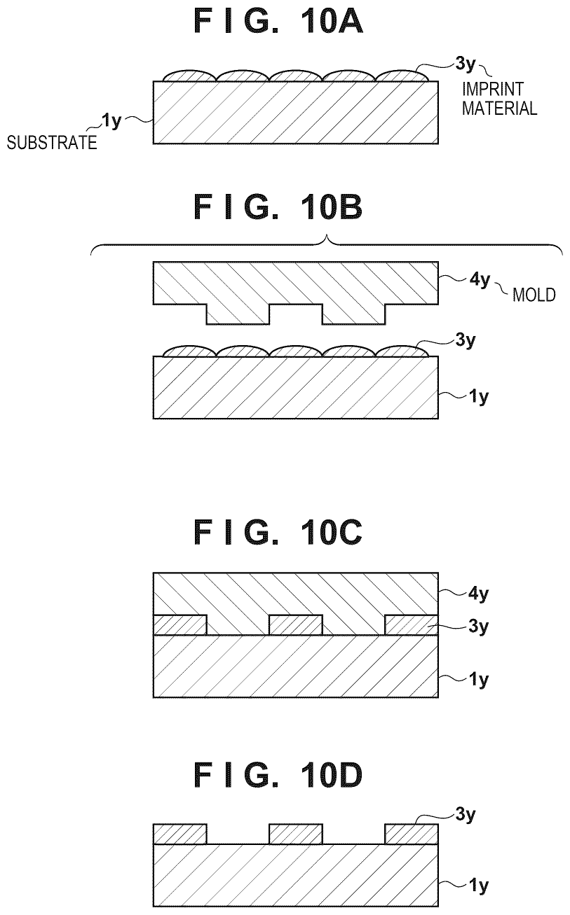

Another article manufacturing method will be described next. As shown in FIG. 10A, a substrate 1y such as silica glass is prepared. Next, an imprint material 3y is applied to the surface of the substrate 1y by an inkjet method or the like. If necessary, a layer of another material such as a metal or a metal compound may be provided on the surface of the substrate 1y.

As shown in FIG. 10B, a side of a mold 4y for imprint with a concave-convex pattern is directed toward and made to face the imprint material 3y on the substrate. As shown in FIG. 10C, the substrate 1y to which the imprint material 3y is applied is brought into contact with the mold 4y, and a pressure is applied. The gap between the mold 4y and the substrate 1y is filled with the imprint material 3y. In this state, when the imprint material 3 is irradiated with light via the mold 4y, the imprint material 3 is cured.

As shown in FIG. 10D, after the imprint material 3y is cured, the mold 4y is separated from the substrate 1y, and the pattern of the cured product of the imprint material 3y is formed on the substrate 1y. Thus, an article including the pattern of the cured product as a constituent member can be obtained. Note that when the substrate 1y is etched using the pattern of the cured product as a mask in the state shown in FIG. 10D, an article with the concave and convex portions reversed with respect to the mold 4y, for example, an imprint mold can be obtained.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-000804, filed Jan. 5, 2024, which is hereby incorporated by reference herein in its entirety.

What is claimed is:

1. A film forming apparatus comprising:
a substrate stage including a substrate holder configured to hold a substrate;
a mold holder configured to hold a mold;
a driving mechanism configured to change an interval between the substrate holder and the mold holder; and
a curing device configured to cure a curable composition in a state in which the curable composition arranged on the substrate and the mold contact each other,
wherein the substrate stage includes a gas blower configured to supply, to the substrate held by the substrate holder, a gas for inhibiting curing of the curable composition.

2. The apparatus according to claim 1, wherein the gas blower is arranged to surround the substrate held by the substrate holder.

3. The apparatus according to claim 2, wherein the gas blower includes a plurality of gas blowholes, and
the plurality of gas blowholes are arranged at equal intervals on a circle concentric with a center of the substrate.

4. The apparatus according to claim 2, wherein the gas blower includes a gas blowhole having a ring shape, and
a center of the ring shape coincides with a center of the substrate held by the substrate holder.

5. The apparatus according to claim 1, further comprising a second gas blower arranged to face the substrate stage and configured to blow a curing inhibition gas for inhibiting curing of the curable composition.

6. The apparatus according to claim 5, wherein the second gas blower selectively blows one of the curing inhibition gas and a filling promotion gas for promoting filling of a space formed between the substrate and the mold with the curable composition.

7. The apparatus according to claim 6, wherein the second gas blower ends blowing of the filling promotion gas before curing the curable composition, and then starts blowing of the curing inhibition gas.

8. The apparatus according to claim 7, wherein after the end of blowing of the filling promotion gas by the second gas blower, the gas blower starts blowing of the gas for inhibiting curing of the curable composition.

9. The apparatus according to claim 5, further comprising a third gas blower arranged to face the substrate stage,
wherein the third gas blower blows a filling promotion gas for promoting filling with the curable composition, to supply the filling promotion gas to a space formed between the substrate and the mold.

10. The apparatus according to claim 9, wherein the third gas blower is arranged between the second gas blower and the mold held by the mold holder.

11. The apparatus according to claim 10, wherein the third gas blower ends blowing of the filling promotion gas before curing the curable composition, and
after the end of blowing of the filling promotion gas by the third gas blower, the gas blower starts supply of the gas for inhibiting curing of the curable composition.

12. The apparatus according to claim 1, wherein a distance between the gas blower and an edge of the substrate falls within a range of 1 mm to 30 mm.

13. The apparatus according to claim 1, wherein the driving mechanism drives at least one of the substrate holder and the mold holder to bring the curable composition and the mold into contact with each other or separate the curable composition and the mold from each other.

14. The apparatus according to claim 1, wherein the mold holder holds, as the mold, a mold having a pattern, and
a film on which the pattern is transferred is formed by curing the curable composition.

15. The apparatus according to claim 1, wherein the mold holder holds, as the mold, a mold having a flat surface, and
a film having a flat surface is formed by curing the curable composition.

16. A film forming method comprising:
bringing a curable composition arranged on a substrate held by a substrate holder and a mold into contact with each other;
supplying, from the substrate holder to the substrate held by the substrate holder, a gas for inhibiting curing of the curable composition;
curing the curable composition in a state in which the curable composition on the substrate and the mold contact each other, thereby forming a film from a cured product of the curable composition; and
separating the film and the mold.

17. The method according to claim 16, further comprising supplying, to a space formed between the substrate and the mold, a filling promotion gas for promoting filling of the space with the curable composition,
wherein the bringing is executed in a state in which the filling promotion gas exists in the space.

18. The method according to claim 17, wherein the supplying is executed after an end of the supplying the filling promotion gas.

19. An article manufacturing method comprising:
forming a film from a cured product of a curable composition on a substrate by a film forming apparatus; and
obtaining an article by processing the substrate having undergone the forming,
wherein the film forming apparatus comprises:
a substrate stage including a substrate holder configured to hold the substrate;
a mold holder configured to hold a mold;
a driving mechanism configured to change an interval between the substrate holder and the mold holder; and
a curing device configured to cure a curable composition in a state in which the curable composition arranged on the substrate and the mold contact each other,
wherein the substrate stage includes a gas blower configured to supply, to the substrate held by the substrate holder, a gas for inhibiting curing of the curable composition.

20. An article manufacturing method comprising:
forming a film from a cured product of a curable composition on a substrate; and
obtaining an article by processing the substrate having undergone the forming,
wherein the forming the film includes:
bringing the curable composition arranged on the substrate held by a substrate holder and a mold into contact with each other;
supplying, from the substrate holder to the substrate held by the substrate holder, a gas for inhibiting curing of the curable composition;
curing the curable composition in a state in which the curable composition on the substrate and the mold contact each other, thereby forming a film from a cured product of the curable composition; and
separating the film and the mold.
